(19) United States
(12) Patent Application Publication
(10) Pub. No.: US 2010/0140623 A1
(43) Pub. Date: Jun. 10, 2010

(54) ARRAY SUBSTRATE FOR DISPLAY DEVICE AND METHOD OF FABRICATING THE SAME

(76) Inventors: Soon-Young MIN, Seoul (KR); Jae-Seok Heo, Yongin-si (KR)

Correspondence Address: BIRCH STEWART KOLASCH & BIRCH, PO BOX 747, FALLS CHURCH, VA, 22040-0747, US

(21) Appl. No.: 12/616,013

(22) Filed: Nov. 10, 2009

(30) Foreign Application Priority Data
Dec. 5, 2008 (KR) 10-2008-0123186

(51) Int. Cl. H01L 33/16; H01L 33/36

(52) U.S. Cl. 257/59; 438/23; 257/40; 257/E33.004; 257/E33.055; 257/E33.062; 977/773

(57) ABSTRACT

An array substrate for a display device includes: a substrate; a gate electrode on the substrate; a gate insulating layer on the gate electrode, the gate insulating layer having an organic-inorganic hybrid material; a semiconductor layer on the gate insulating layer over the gate electrode; source and drain electrodes spaced apart from each other on the semiconductor layer; a passivation layer on the source and drain electrodes, the passivation layer having a drain contact hole exposing the drain electrode; and a pixel electrode on the passivation layer, the pixel electrode connected to the drain electrode through the drain contact hole.

This application claims the benefit of Korean Patent Application No. 10-2008-0123186, filed in Korea on Dec. 5, 2008, which is hereby incorporated by reference in its entirety.

### BACKGROUND OF THE INVENTION

### 1. Field of the Invention

The present application relates to an array substrate for a display device, and more particularly, to an array substrate where a thin film transistor has a gate insulating layer of high dielectric constant and a method of fabricating the array substrate.

2. Discussion of the Related Art

Cathode ray tube (CRT) devices have been widely used for a television, a measuring instrument and an information terminal. However, the CRT devices cannot respond to a request for miniaturization and lightweight of electronic goods because of their heavy weight and large volume. Accordingly, flat panel display (FPD) devices having light weight, thin profile, and low power consumption have been substituted for CRT devices. Liquid crystal display (LCD) devices, plasma display panel (PDP) devices, field emission display (FED) devices, and electroluminescent display (ELD) devices are examples of the FPD devices.

Among FPD devices, the LCD devices have been widely used because of their excellent characteristics of high resolution, high contrast ratio and displaying moving images. In general, an LCD device includes a liquid crystal panel having facing two substrates and a liquid crystal layer between the two substrates, a backlight unit and a driving circuit unit. The two substrates are fabricated by repetition of a thin film deposition, a photolithography and an etching to have an array layer and a color filter layer. The two substrates may be referred to as an array substrate and a color filter substrate. A seal pattern is formed on one of the two substrates and the two substrates are attached to each other with a liquid crystal layer interposed between the two substrates, thereby the liquid crystal panel completed. Further, the driving circuit is connected to the liquid crystal panel, and the liquid crystal panel is modularized with the backlight unit to constitute the LCD device. The array layer includes a thin film transistor and a conductive line formed by deposition and etching of a conductive material, a semiconductor material and an insulating material.

FIG. 1 is a cross-sectional view showing an array substrate for a display device according to the related art.

In FIG. 1, a thin film transistor (TFT) T is formed on a substrate 10. The TFT T includes a gate electrode 3, a gate insulating layer 5 on the gate electrode 3, a semiconductor layer 7 on the gate insulating layer 5 and source and drain electrodes 9 and 11 on the semiconductor layer 7. A passivation layer 13 is formed on the source and drain electrodes 9 and 11. The passivation layer 13 includes a drain contact hole 13a exposing the drain electrode 11. In addition, a pixel electrode 15 connected to the drain electrode 11 through the drain contact hole 13a is formed on the passivation layer 13.

The gate insulating layer 5 includes an inorganic insulating material such as silicon nitride (SiNx) having a dielectric constant of about 6 to about 8. However, since the gate insulating layer 5 of an inorganic insulating material is formed by a plasma enhanced chemical vapor deposition (PECVD) apparatus of high price, fabrication cost for the gate insulating layer 5 increases. In addition, since uniform and sufficient thickness can not be obtained by a single deposition step, the gate insulating layer 5 of an inorganic insulating material is formed by at least two deposition steps to obtain uniform and sufficient thickness. As a result, fabrication process becomes complicated, and production yield and fabrication efficiency are reduced.

Recently, to solve the above problems of an inorganic insulating material, an organic insulating material has been used for the gate insulating layer because of its low cost and simple fabrication process. However, since the organic insulating material has a dielectric constant lower than the inorganic insulating material, a capacitance of a storage capacitor (not shown) connected to the TFT T is reduced and a kick-back voltage causing deterioration of the LCD device such as a flicker increases. Further, characteristics of the TFT T such as an on current, a threshold voltage and a mobility are deteriorated due to the low dielectric constant of the organic insulating material.

### SUMMARY OF THE INVENTION

Accordingly, embodiments of the invention are directed to a method of fabricating a liquid crystal display device that substantially obviates one or more of problems due to limitations and disadvantages of the related art.

An advantage of the invention is to provide an array substrate for a display device where a display quality is improved by using a gate insulating layer having a relatively high dielectric constant for a thin film transistor.

Another advantage of the present invention is to provide an array substrate for a display device where a kick-back voltage is reduced by increasing a capacitance of a storage capacitor.

Another advantage of the present invention is to provide a method of fabricating an array substrate for a display device where a fabrication cost for a gate insulating layer is reduced and a fabrication efficiency is improved.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the invention, as embodied and broadly described, according to an aspect of the invention, an array substrate for a display device includes: a substrate; a gate electrode on the substrate; a gate insulating layer on the gate electrode, the gate insulating layer having an organic-inorganic hybrid material; a semiconductor layer on the gate insulating layer over the gate electrode; source and drain electrodes spaced apart from each other on the semiconductor layer; a passivation layer on the source and drain electrodes, the passivation layer having a drain contact hole exposing the drain electrode; and a pixel electrode on the passivation layer, the pixel electrode connected to the drain electrode through the drain contact hole.

Another aspect, a method of fabricating an array substrate for a display device includes: forming a gate electrode on a substrate; forming a gate insulating layer on the gate electrode, the gate insulating layer having an organic-inorganic hybrid material; forming a semiconductor layer on the gate insulating layer over the gate electrode; forming source and drain electrodes spaced apart from each other on the semiconductor layer; forming a passivation layer on the source and drain electrodes, the passivation layer having a drain contact hole exposing the drain electrode; and forming a pixel electrode on the passivation layer, the pixel electrode connected to the drain electrode through the drain contact hole.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 is a cross-sectional view showing an array substrate for a display device according to the related art;

FIG. 2 is a cross-sectional view showing a liquid crystal display device according to an embodiment of the present invention;

FIG. 3 is a cross-sectional view showing an array substrate for a display device according to an embodiment of the present invention;

FIG. 4 is a graph showing a drain current I_{D} and a gate voltage V_{G} of a thin film transistor for an array substrate according to an embodiment of the present invention;

FIG. 5 is a view showing an organic polymer solution including a metal oxide nano-particle for a gate insulating layer of a thin film transistor according to an embodiment of the present invention; and

FIGS. 6A to 6F are cross-sectional view showing a method of fabricating an array substrate for a display device according to an embodiment of the present invention.

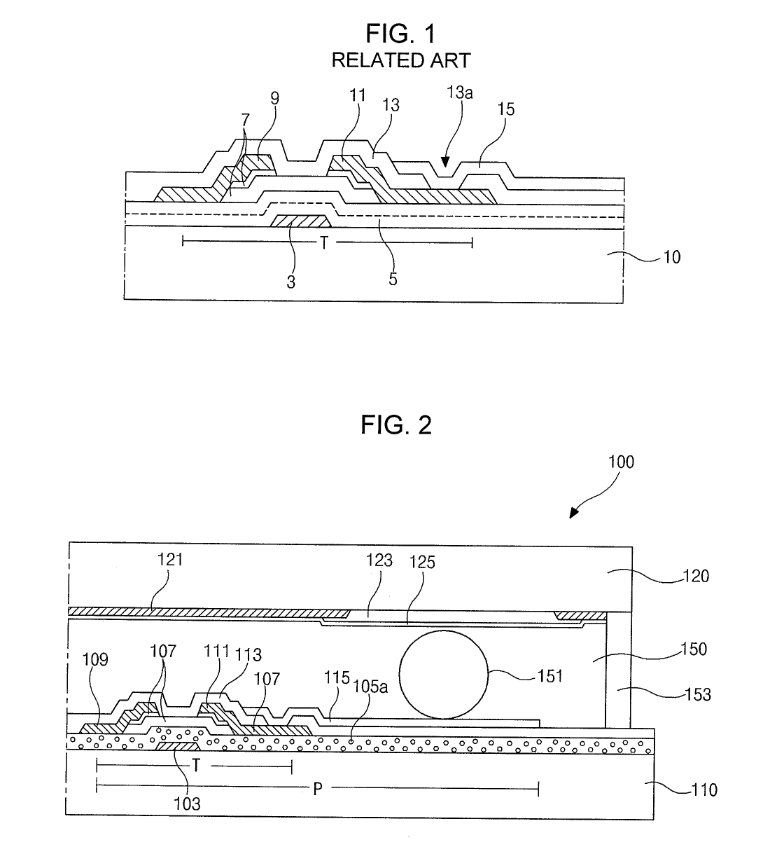

### DETAILED DESCRIPTION OF THE PREFERRED EMBODIMENTS

Reference will now be made in detail to the illustrated embodiments of the present invention, which are illustrated in the accompanying drawings.

FIG. 2 is a cross-sectional view showing a liquid crystal display device according to an embodiment of the present invention.

In FIG. 2, a liquid crystal panel 100 includes first and second substrates 110 and 120 facing and spaced apart from each other and a liquid crystal layer 150 between the first and second substrates 110 and 120. The first and second substrates 110 and 120 may be referred to as array and color filter substrates, respectively. A gate line (not shown) and a data line (not shown) are formed on an inner surface of the first substrate 110. The gate line and the data line cross each other to define a pixel region P and a pixel electrode 115 is formed in the pixel region P.

In addition, a thin film transistor (TFT) T including a gate electrode 103, a gate insulating layer 105, a semiconductor layer 107, a source electrode 109 and a drain electrode 111 is connected to the gate line and the data line. The gate insulating layer 105 is formed of an organic-inorganic hybrid material including a metal oxide nano-particle 105a. For example, the gate insulating layer 105 may be formed by a coating method to have a predetermined thickness. As a result, characteristics of the TFT T such as an on current, a threshold voltage and a mobility are improved. A passivation layer 113 is formed on the TFT T, and the pixel electrode 115 is formed on the passivation layer 113. The pixel electrode 115 is electrically connected to the drain electrode 111.

A black matrix 121 corresponding to the gate line, the data line, the TFT T and a boundary portion of the pixel electrode 115 is formed on an inner surface of the second substrate 120. The black matrix 121 shields a non-display area to prevent a light leakage. A color filter layer 123 including red, green and blue color filters is formed on black matrix 121 and the inner surface of the second substrate 120 exposed through an opening of the black matrix 121. A common electrode 125 is formed on the black matrix 121 and the color filter layer 123.

A liquid crystal layer 150 is formed between the pixel electrode 115 and the common electrode 125. In addition, first and second orientation films (not shown) are formed between the liquid crystal layer 150 and the pixel electrode 115 and between the liquid crystal layer 150 and the common electrode 125. The first and second orientation films may be rubbed to align liquid crystal molecules of the liquid crystal layer 150 along a predetermined direction and an initial alignment state of the liquid crystal molecules is obtained. A spacer 151 is formed in the liquid crystal layer 150 to keep a uniform cell gap between the first and second substrates 110 and 120. Further, a seal pattern 153 is formed at a boundary portion between the first and second substrates 110 and 120 to attach the first and second substrates 110 and 120 and to prevent leakage of the liquid crystal molecules in the liquid crystal layer 150.

First and second polarizing plates (not shown) are formed on outer surfaces of the first and second substrates 110 and 120, respectively, to selectively transmitting a polarized light. A backlight unit (not shown) supplying a light is formed under the liquid crystal panel 100 to constitute a liquid crystal display (LCD) device. The backlight unit may include a plurality of lamps and an inverter supplying a power to the plurality of lamps.

The TFT T is selectively transmits a data signal to the pixel electrode 115 by turning on/off the TFT T according to a gate signal, and an alignment direction of the liquid crystal molecules in the liquid crystal layer 150 is adjusted by an electric field generated between the pixel electrode 115 and the common electrode 125.

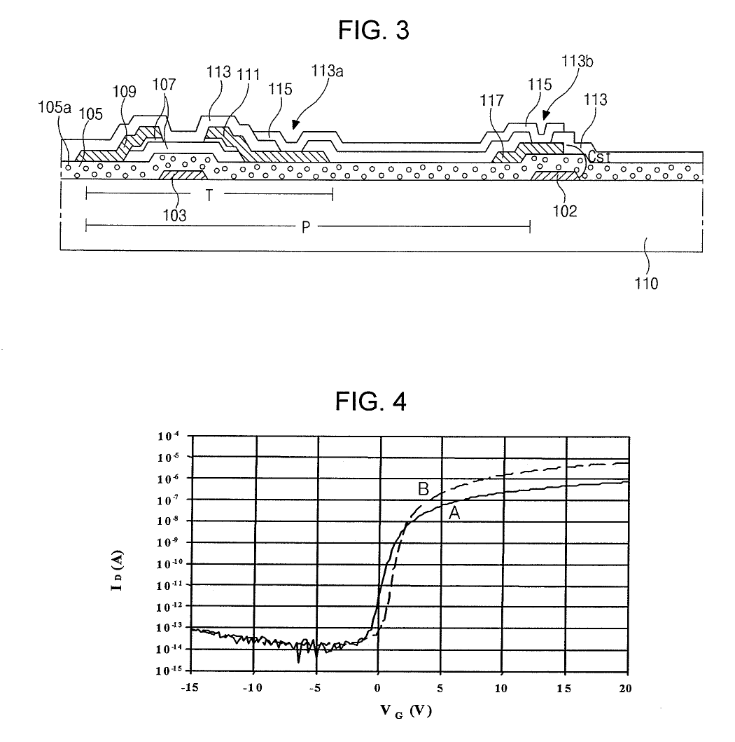

FIG. 3 is a cross-sectional view showing an array substrate for a display device according to an embodiment of the present invention.

In FIG. 3, a gate line 102 and a gate electrode 103 connected to the gate line 102 are formed on a substrate 110 having a pixel region P, and a gate insulating layer 105 is formed on the gate line 102 and the gate electrode 103. A semiconductor layer 107 is formed on the gate insulating layer over the gate electrode 103, and source and drain electrodes 109 and 111 spaced apart from each other are formed on the semiconductor layer 107. The gate electrode 103, the semiconductor layer 107, the source electrode 109 and the drain electrode 111 constitute a thin film transistor (TFT) T. In addition, a metal pattern 117 is formed on the gate insulating layer 105 over the gate line 102.

A passivation layer 113 is formed on the source and drain electrodes 109 and 111 and the metal pattern 117, and a pixel electrode 115 is formed on the passivation layer 113 in the pixel region P. The passivation layer 113 has a drain contact hole 113a exposing the drain electrode 111 and a capacitor contact hole 113b exposing the metal pattern 117. The pixel electrode 115 is connected to the drain electrode 111 through the drain contact hole 113a and connected to the metal pattern 117 through the capacitor hole 113b. The pixel electrode 115 overlaps the gate line 102 to constitute a storage capacitor Cst. An overlapped portion of the gate line 102 and the metal pattern 117 connected to the pixel electrode 115 are used as first and second capacitor electrodes, respectively, of the storage capacitor Cst, and the gate insulating layer 105 is used as a dielectric layer of the storage capacitor Cst.

Since the gate insulating layer 105 is formed of an organic-inorganic hybrid material including a metal oxide nano-particle 105a, the gate insulating layer 105 has a dielectric constant of about 9 to about 10. As a result, a capacitance of the storage capacitor Cst increases and a kick-back voltage of the TFT T is reduced.

A kick-back voltage of the TFT T is determined by an equation (1).

ΔVp=Cgs/(Cst+Cgs+Clc) equation (1)

,where ΔVp is a kick-back voltage, Cgs is a parasitic capacitance between a gate electrode and a source electrode, Cst is a storage capacitance of the storage capacitor and Clc is a liquid crystal capacitance of a liquid crystal cell in the pixel region P.

When the TFT T is changed from a turn-on state to a turn-off state, the kick-back voltage ΔVp is generated at the pixel electrode 115 according to the equation (1), and a pixel voltage of the pixel electrode 115 is reduced by the kick-back voltage ΔVp. The kick-back voltage causes deterioration of a display device such as a flicker, an image sticking and a non-uniformity of brightness. Since the kick-back voltage ΔVp is inversely proportional to the storage capacitance Cst, the kick-back voltage ΔVp is reduced by increasing the storage capacitance Cst.

In addition, a capacitance of a capacitor is determined by an equation (2).

C=εA/d equation (2)

, where C is a capacitance, ε is a dielectric constant of a dielectric layer, A is an area of an electrode, and d is a distance between two electrodes.

Since the storage capacitance Cst is proportional to a dielectric constant, the storage capacitance Cst is increased by increasing the dielectric constant ε. The dielectric constant ε of the gate insulating layer 105 is increased by using the organic-inorganic hybrid material including the metal oxide nano-particle 105a. As a result, the kick-back voltage ΔVp is reduced by using the gate insulating layer 105 of the organic-inorganic hybrid material including the metal oxide nano-particle 105a. Further, the deterioration of the display device such as a flicker, an image sticking and a non-uniformity in brightness is prevented, and a display quality of the display device is improved.

Moreover, since the gate insulating layer 105 is formed on the substrate 110 through a coating method or a printing method instead of a plasma enhanced chemical vapor deposition (PECVD) method, a fabrication cost is reduced and a fabrication process is simplified. Further, since an induction of a channel in the semiconductor layer 107 by a gate voltage of the gate electrode 103 is proportional to the dielectric constant c of the gate insulating layer 105, a generation of a front channel in the semiconductor layer 107 is improved, and characteristics of the TFT T is improved.

FIG. 4 is a graph showing a drain current I_{D} and a gate voltage V_{G} of a thin film transistor for an array substrate according to an embodiment of the present invention.

In FIG. 4, a drain current I_{D} is measured while a gate voltage V_{G} increases from about −15V to about 20V. A first curve A represents a thin film transistor (TFT) including a gate insulating layer of silicon nitride (SiNx), and a second curve B represents a TFT including a gate insulating layer 105 of an organic-inorganic hybrid material having a metal oxide nano-particle 105a of the present invention. An OFF current may be defined by the drain current I_{D} at the gate voltage of about −5V, and an ON current may be defined by the drain current I_{D} at the gate voltage of about 10V. An ON-OFF ratio may be defined by a ratio of the ON current to the OFF current, and characteristics such as a switching property are improved by increasing the ON-OFF ratio.

Since the ON-OFF ratio of the second curve B has greater than the ON-OFF ratio of the first curve A, the TFT T including a gate insulating layer 105 of an organic-inorganic hybrid material having a metal oxide nano-particle 105a is turned on even by a relatively lower gate voltage as compared with the TFT including a gate insulating layer of silicon nitride (SiNx). In addition, since the ON current of the second curve B is greater than the ON current of the first curve A, a mobility of TFT T including a gate insulating layer 105 of an organic-inorganic hybrid material having a metal oxide nano-particle 105a is improved as compared with the TFT including a gate insulating layer of silicon nitride (SiNx). Accordingly, the characteristics of the TFT T including a gate insulating layer 105 of an organic-inorganic hybrid material having a metal oxide nano-particle 105a are improved as compared with the characteristics of the TFT including a gate insulating layer of silicon nitride (SiNx).

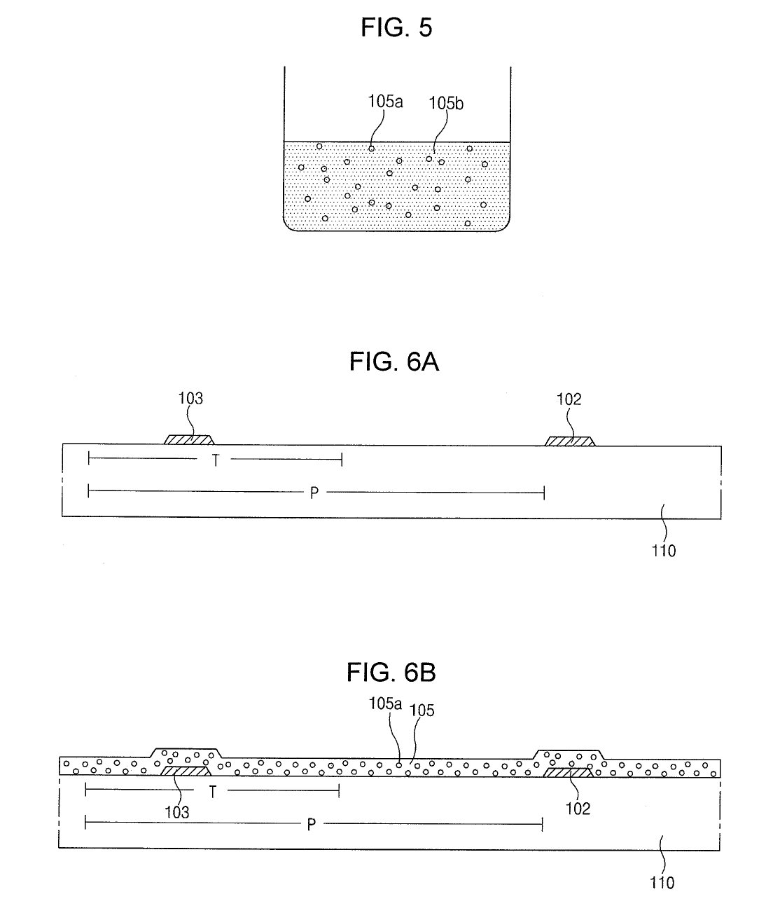

FIG. 5 is a view showing an organic polymer solution including a metal oxide nano-particle for a gate insulating layer of a thin film transistor according to an embodiment of the present invention.

The gate insulating layer 105 may be formed of an organic-inorganic hybrid material including a metal oxide nano-particle by a sol-gel method using an organic polymer solution. In FIG. 5, a metal oxide nano-particle 105a having a dielectric constant of about 8 is dispersed in a solution 105b including an organic polymer. As a result, the organic polymer solution 105b has a dielectric constant of about 6 to about 10. The organic polymer may include at least one of siloxane polymer, polyacrylate polyimide and polyester. For example, the organic polymer may have a co-polymer including at least two of siloxane polymer, polyacrylate polyimide and polyester. In addition, the metal oxide nano-particle 105a may include one of zinc oxide (ZnO), barium strontium titanate (BST), barium zirconate titanate (BZT), lead zirconate titanate (PZT), strontium titanate, barium titanate, barium magnesium fluoride (BMF), bismuth titanate, strontium bismuth tantalate (SBT) strontium bismuth niobate (SBN), silicon oxide (SiO₂), titanium oxide (TiO₂), aluminum oxide (Al₂O₃), magnesium oxide (MgO), zinc sulfate (ZnSO₄), hafnium sulfate (Hf(SO₄)₂), yttrium oxide (Y₂O₃), lanthanum oxide (La₂O₃), tantalum oxide (Ta₂O₅) and barium oxide (BaO).

The metal oxide nano-particle 105a may be dispersed by a physical force and a chemical force. For example, the metal oxide nano-particle 105a may be dispersed in the organic polymer 105b by agitation using a physical force such as a shear force. Alternatively, the metal oxide nano-particle 105a may be dispersed in the organic polymer solution 105b by a chemical bond using a chemical force. Accordingly, the gate insulating layer 105 may be formed by coating the organic polymer solution 105b on the substrate 110 or by printing the organic polymer solution 105b on the substrate 110.

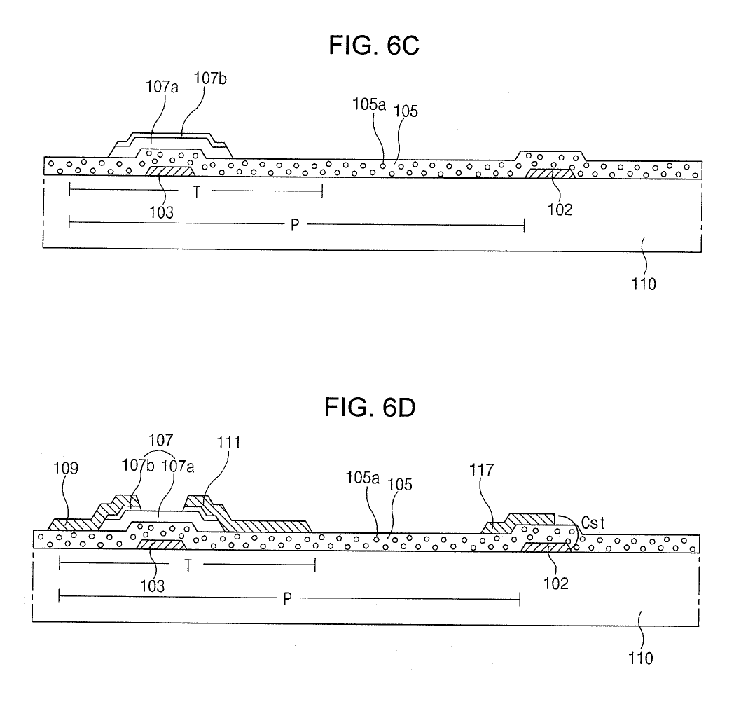

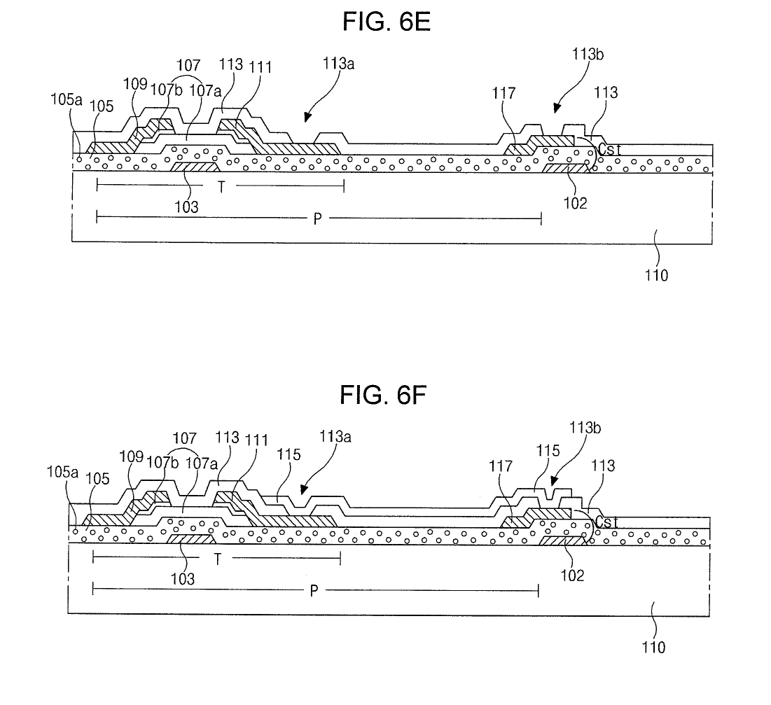

FIGS. 6A to 6F are cross-sectional view showing a method of fabricating an array substrate for a display device according to an embodiment of the present invention.

In FIG. 6A, a gate line 102 and a gate electrode 103 connected to the gate line 102 are formed on a substrate 110 having a pixel region P by depositing and patterning a first metallic material. The substrate 110 may include one of glass and plastic, and the first metallic material may include one of aluminum (Al), aluminum alloy such as aluminum neodymium (AlNd), molybdenum (Mo) and chromium (Cr). In addition, the gate line 102 and the gate electrode 104 may include a double layer of aluminum (Al) and molybdenum (Mo) or a double layer of aluminum neodymium (AlNd) and molybdenum (Mo).

In FIG. 6B, a gate insulating layer 105 of an organic-inorganic hybrid material including a metal oxide nano-particle 105a is formed on the gate line 102 and the gate electrode 103. Since the gate insulating layer 105 has a dielectric constant of about 9 to about 10, a capacitance of a storage capacitor increases and a kick-back voltage is reduced. As a result, a display quality of a display device having the array substrate is improved.

Further, the gate insulating layer 105 may be formed through one of a spin coating method, a slit coating method, a roll coating method, a printing method and an inkjet coating method. Since the gate insulating layer 105 is formed by a method cheaper than a deposition method, a fabrication cost of a display device is reduced.

In FIG. 6C, an active layer 107a and an ohmic contact layer 107b are sequentially formed on the gate insulating layer 105 over the gate electrode 103 by depositing and patterning intrinsic amorphous silicon (a-Si:H) and impurity-doped amorphous silicon (n+a-Si:H).

In FIG. 6D, source and drain electrodes 109 and 111 are formed on the ohmic contact layer 107b by depositing and patterning a second metallic material. In addition, a data line (not shown) crossing the gate line 102 and connected to the source electrode 109 is formed on the gate insulating layer 105. Each of the source electrode 109, the drain electrode 111 and the data line may include a single layer of one of chromium (Cr), aluminum alloy, molybdenum (Mo), titanium (Ti), copper (Cu) and copper alloy or a double layer of one of copper/molybdenum (Cu/Mo), copper/titanium (Cu/Ti), copper/indium-tin-oxide (Cu/ITO) and molybdenum/aluminum neodymium (Mo/AlNd). Further, each of the source electrode 109, the drain electrode 111 and the data line may include a triple layer of one of chromium/aluminum neodymium/chromium (Cr/AlNd/Cr) and molybdenum/aluminum neodymium/molybdenum (Mo/AlNd/Mo).

Moreover, a metal pattern 117 of an island shape is formed on the gate insulating layer 105 over the gate line 102 to constitute a storage capacitor Cst using an overlapped portion of the gate line 102 and the metal pattern 117 as first and second capacitor electrodes, respectively, and using the gate insulating layer 105 as a dielectric layer.

A central portion of the ohmic contact layer 107b is removed using the source and drain electrodes 109 and 111 as an etching mask, thereby a central portion of the active layer 107a exposed. The active layer 107a and the ohmic contact layer 107b constitute a semiconductor layer 107. Further, the gate electrode 103, the semiconductor layer 107, the source electrode 109 and the drain electrode 111 constitute a thin film transistor (TFT) T.

In FIG. 6E, a passivation layer 113 is formed on the source and drain electrodes 109 and 111 by depositing and patterning an organic insulating material such as benzocyclobutene (BCB) and acrylic resin. The passivation layer 113 is patterned to have a drain contact hole 113a exposing the drain electrode 111 and a capacitor contact hole 113b exposing the metal pattern 117.

In FIG. 6F, a pixel electrode 115 is formed on the passivation layer 113 by depositing and patterning a transparent conductive material such as indium-tin-oxide (ITO) and indium-zinc-oxide (IZO). The pixel electrode 115 is formed in the pixel region P to be connected to the drain electrode 111 through the drain contact hole 113a and connected to the metal pattern 117 through the capacitor contact hole 113b.

Consequently, since the gate insulating layer 105 of the TFT T is formed of an organic-inorganic hybrid material including a metal oxide nano-particle, the gate insulating layer 105 has a relatively high dielectric constant. As a result, a kick-back voltage of the TFT T is reduced due to increase of a capacitance of the storage capacitor Cst, and a display quality of a display device is improved. Moreover, since the gate insulating layer 105 is formed on the substrate 110 through a coating method or a printing method instead of a chemical vapor deposition (CVD) method, a fabrication cost is reduced, a fabrication process is simplified and a production yield is improved. In addition, since a channel is generated even by a relatively low gate voltage of the gate electrode 103 through the gate insulating layer 105, characteristics of the TFT T are improved.

Although the TFT T having a bottom gate structure where the semiconductor layer 107 is formed over the gate electrode 103 is shown in FIGS. 6A to 6F, a TFT having a top gate structure where a gate electrode is formed on a semiconductor layer may include a gate insulating layer of an organic-inorganic hybrid material including a metal oxide nano-particle. In addition, although the array substrate 110 is illustrated to be used for a liquid crystal display (LCD) device in FIGS. 6A to 6F, an array substrate where a TFT having a gate insulating layer of an organic-inorganic hybrid material including a metal oxide nano-particle may be used for another display device such as an organic electroluminescent display device, an electronic paper and a flexible display device of a plastic thin film transistor liquid crystal display (TFT-LCD) device.

It will be apparent to those skilled in the art that various modifications and variations can be made in an array substrate for a display device and a method of fabricating an array substrate of embodiments of the invention without departing from the spirit or scope of the invention. Thus, it is intended that embodiments of the invention cover the modifications and variations of this invention provided they come within the scope of the appended claims and their equivalents.

What is claimed is:

1. An array substrate for a display device, comprising:
a substrate;
a gate electrode on the substrate;
a gate insulating layer on the gate electrode, the gate insulating layer having an organic-inorganic hybrid material;
a semiconductor layer on the gate insulating layer over the gate electrode;
source and drain electrodes spaced apart from each other on the semiconductor layer;
a passivation layer on the source and drain electrodes, the passivation layer having a drain contact hole exposing the drain electrode; and
a pixel electrode on the passivation layer, the pixel electrode connected to the drain electrode through the drain contact hole.

2. The substrate according to claim 1, wherein the semiconductor layer includes an active layer of intrinsic amorphous silicon on the gate insulating layer and an ohmic contact layer of impurity-doped amorphous silicon on the active layer.

3. The substrate according to claim 1, wherein the gate insulating layer has a dielectric constant of about 6 to about 10.

4. The substrate according to claim 1, wherein the organic-inorganic hybrid material includes an organic polymer and a metal oxide nano-particle dispersed in the organic polymer.

5. The substrate according to claim 4, wherein the organic polymer includes at least one of siloxane polymer, polyacrylate polyimide and polyester.

6. The substrate according to claim 4, wherein the metal oxide nano-particle includes one of zinc oxide (ZnO), barium strontium titanate (BST), barium zirconate titanate (BZT), lead zirconate titanate (PZT), strontium titanate, barium titanate, barium magnesium fluoride (BMF), bismuth titanate, strontium bismuth tantalate (SBT) strontium bismuth niobate (SBN), silicon oxide (SiO₂), titanium oxide (TiO₂), aluminum oxide (Al₂O₃), magnesium oxide (MgO), zinc sulfate (ZnSO₄), hafnium sulfate (Hf(SO₄)₂), yttrium oxide (Y₂O₃), lanthanum oxide (La₂O₃), tantalum oxide (Ta₂O₅) and barium oxide (BaO).

7. The substrate according to claim 1, wherein the display device includes one of a liquid crystal display device, an organic electroluminescent display device, an electronic paper and a flexible display device.

8. The substrate according to claim 1, further comprising a gate line connected to the gate electrode, a data line connected to the source electrode and a metal pattern between the gate insulating layer and the passivation layer.

9. The substrate according to claim 8, wherein the passivation layer has a capacitor contact hole exposing the metal pattern and the pixel electrode is connected to the metal pattern through the capacitor contact hole, and wherein the metal pattern overlaps the gate line to constitute a storage capacitor using an overlapped portion of the gate line as a first capacitor electrode, using the metal pattern as a second capacitor electrode and using the gate insulating layer as a dielectric layer.

10. A method of fabricating an array substrate for a display device, comprising:
forming a gate electrode on a substrate;
forming a gate insulating layer on the gate electrode, the gate insulating layer having an organic-inorganic hybrid material;
forming a semiconductor layer on the gate insulating layer over the gate electrode;
forming source and drain electrodes spaced apart from each other on the semiconductor layer;
forming a passivation layer on the source and drain electrodes, the passivation layer having a drain contact hole exposing the drain electrode; and
forming a pixel electrode on the passivation layer, the pixel electrode connected to the drain electrode through the drain contact hole.

11. The method according to claim 10, wherein forming the semiconductor layer comprises:
forming an active layer of intrinsic amorphous silicon on the gate insulating layer; and
forming an ohmic contact layer of impurity-doped amorphous silicon on the active layer.

12. The method according to claim 10, wherein the gate insulating layer is formed by one of a spin coating method, a slit coating method, a roll printing method and an inkjet coating method.

13. The method according to claim 10, wherein the gate insulating layer has a dielectric constant of about 6 to about 10.

14. The method according to claim 10, wherein the organic-inorganic hybrid material includes an organic polymer and a metal oxide nano-particle dispersed in the organic polymer.

15. The method according to claim 14, wherein the organic polymer includes at least one of siloxane polymer, polyacrylate polyimide and polyester.

16. The method according to claim 14, wherein the metal oxide nano-particle includes one of zinc oxide (ZnO), barium strontium titanate (BST), barium zirconate titanate (BZT), lead zirconate titanate (PZT), strontium titanate, barium titanate, barium magnesium fluoride (BMF), bismuth titanate, strontium bismuth tantalate (SBT) strontium bismuth niobate (SBN), silicon oxide (SiO₂), titanium oxide (TiO₂), aluminum oxide (Al₂O₃), magnesium oxide (MgO), zinc sulfate (ZnSO₄), hafnium sulfate (Hf(SO₄)₂), yttrium oxide (Y₂O₃), lanthanum oxide (La₂O₃), tantalum oxide (Ta₂O₅) and barium oxide (BaO).

17. The method according to claim 10, further comprising:
forming a gate line connected to the gate electrode; and
forming a data line connected to the source electrode and a metal pattern between the gate insulating layer and the passivation layer.

18. The method according to claim 17, wherein the passivation layer has a capacitor contact hole exposing the metal pattern and the pixel electrode is connected to the metal pattern through the capacitor contact hole, and wherein the metal pattern overlaps the gate line to constitute a storage capacitor using an overlapped portion of the gate line as a first capacitor electrode, using the metal pattern as a second capacitor electrode and using the gate insulating layer as a dielectric layer.
